(19) United States
(12) Patent Application Publication
(10) Pub. No.: US 2026/0053050 A1
(43) Pub. Date: Feb. 19, 2026

(54) ELECTRICAL POWER MODULE AND ELECTRONICS PACKAGE

(71) Applicant: FABRIC8LABS, INC., San Diego, CA (US)

(72) Inventors: Guillermo Romero, Phoenix, AZ (US); Ian Winfield, Oceanside, CA (US); Joseph Madril, San Diego, CA (US); Michael Matthews, Encinitas, CA (US)

(21) Appl. No.: 19/079,279

(22) Filed: Mar. 13, 2025

Related U.S. Application Data
(60) Provisional application No. 63/682,884, filed on Aug. 14, 2024.
(60) Provisional application No. 63/698,166, filed on Sep. 24, 2024.

(51) Int. Cl. H01L 23/31; B29C 64/209; C25D 1/00; H01L 21/288; H01L 23/433

(52) U.S. Cl. CPC H01L 23/3128; C25D 1/003; H01L 21/2885; H01L 23/315; H01L 23/4334; B29C 64/209

(57) ABSTRACT

An electrical power module includes a base plate, including an electrically isolating substrate and a first metallic layer formed on a first side of the electrically isolating substrate. The electrical power module also includes electrical connection pillars extending from the first metallic layer. The electrical power module further includes at least one encapsulant retention feature extending from the first metallic layer and including at least one surface that is angled or parallel relative to the first side of the electrically isolating substrate and faces the first side of the electrically isolating substrate. The electrical power module additionally includes at least one electrical component electrically coupled with the metallic layer of the base plate. The electrical power module further includes an encapsulant encapsulating the at least one electrical component, the metallic layer, and the at least one encapsulant retention feature and partially encapsulating the electrical connection pillars.

### CROSS-REFERENCE TO RELATED APPLICATIONS

This application claims the benefit of U.S. Provisional Patent Application No. 63/682,884, filed Aug. 14, 2024, and U.S. Provisional Patent Application No. 63/698,166, filed Sep. 24, 2024, both of which are incorporated herein by reference in their entireties.

### FIELD

This disclosure relates generally to electrochemical deposition methods and systems, and the associated parts made thereby, and more particularly to methods of making an electrical power module and methods of making an electronics package for an electrical power module that uses an electrochemical deposition system.

### BACKGROUND

Electrochemical deposition manufacturing utilizes electrochemical reactions to manufacture parts in an additive manufacturing manner. In an electrochemical deposition manufacturing process, a metal part is constructed by plating charged metal ions onto a surface of a cathode in an electrolyte solution. This technique relies on placing a deposition anode physically close to the cathode in the presence of a deposition solution (the electrolyte), and energizing the anode causing charge to flow through the anode. This creates an electrochemical reduction reaction to occur at the cathode near the anode and deposition of material on the cathode.

Although conventional electrochemical deposition manufacturing processes can make parts that other types of manufacturing processes are incapable of making, such conventional electrochemical deposition manufacturing processes are not fully capable of making certain types of parts with difficult to manufacture features.

### SUMMARY

The subject matter of the present application has been developed in response to the present state of the art, and in particular, in response to the shortcomings of conventional electrochemical deposition manufacturing processes for making certain types of parts, such as electrical power modules, electronics packages for electrical power modules, and the like, which have not yet been fully solved by currently available techniques. Accordingly, the subject matter of the present application has been developed to provide methods of making electrical power modules and/or electronic packages for electrical power modules, and the corresponding electrical power modules and/or the electronic packages made by such methods, which overcome at least some of the shortcomings of prior art techniques.

The following is a non-exhaustive list of examples, which may or may not be claimed, of the subject matter, disclosed herein.

Disclosed herein is a method of making an electronics package for an electrical power module, the electrical power module having an encapsulant encapsulating an electrical-component side of the electronics package. The method includes positioning a base plate, including an electrically isolating substrate and a first metallic layer formed on a first side of the electrically isolating substrate, into an electrolyte solution such that the first metallic layer of the base plate directly contacts the electrolyte solution. The first side of the electrically isolating substrate corresponds to the electrical-component side of the electronics package. The method also includes positioning a deposition anode array, including a plurality of deposition anodes, into the electrolyte solution such that a gap is established between the first metallic layer and the plurality of deposition anodes. The method further includes connecting the first metallic layer to a power source. The method additionally includes connecting one or more deposition anodes of the plurality of deposition anodes to the power source. The method also includes transmitting electrical energy from the power source through the one or more deposition anodes of the plurality of deposition anodes, through the electrolyte solution, and to the first metallic layer, such that material is deposited onto the first metallic layer and forms an electrical connection pillar, an electrical-component retention feature, and an encapsulant retention feature of the electronics package. The encapsulant retention feature is configured to interact with the encapsulant and to retain the encapsulant on the electrical-component side of the electronics package when the encapsulant encapsulates the electrical-component side of the electronics package. The preceding subject matter of this paragraph characterizes example 1 of the present disclosure.

The electrical connection pillar includes an electrical signal connection pillar. The preceding subject matter of this paragraph characterizes example 2 of the present disclosure, wherein example 2 also includes the subject matter according to example 1, above.

The electrical connection pillar has a cylindrical shape. The preceding subject matter of this paragraph characterizes example 3 of the present disclosure, wherein example 3 also includes the subject matter according to example 2, above.

The electrical connection pillar includes an electrical power connection pillar. The preceding subject matter of this paragraph characterizes example 4 of the present disclosure, wherein example 4 also includes the subject matter according to any of examples 1-3, above.

The electrical connection pillar has a rectangular shape. The preceding subject matter of this paragraph characterizes example 5 of the present disclosure, wherein example 5 also includes the subject matter according to example 4, above.

The material deposited onto the first metallic layer forms at least two electrical connection pillars. The electrical connection pillars include an electrical signal connection pillar and an electrical power connection pillar. The electrical signal connection pillar has a first shape. The electrical signal connection pillar has a first shape. The first shape is different than the second shape. The preceding subject matter of this paragraph characterizes example 6 of the present disclosure, wherein example 6 also includes the subject matter according to any of examples 1-5, above.

The encapsulant retention feature is co-formed with the electrical connection pillar. The preceding subject matter of this paragraph characterizes example 7 of the present disclosure, wherein example 7 also includes the subject matter according to any of examples 1-6, above.

The encapsulant retention feature includes one of a mesh, an overhang, a concave surface, a convex surface, a gyroid, or a hole. The preceding subject matter of this paragraph characterizes example 8 of the present disclosure, wherein example 8 also includes the subject matter according to example 7, above.

The electrical-component retention feature includes guides for receiving and retaining an electrical component of the electrical power module. The preceding subject matter of this paragraph characterizes example 9 of the present disclosure, wherein example 9 also includes the subject matter according to any of examples 1-8, above.

The electrical-component retention feature includes an overhang and defines a slot for slidably receiving an electrical component of the electrical power module. The preceding subject matter of this paragraph characterizes example 10 of the present disclosure, wherein example 10 also includes the subject matter according to any of examples 1-9, above.

The electrical-component retention feature includes at least one electrical connector. The preceding subject matter of this paragraph characterizes example 11 of the present disclosure, wherein example 11 also includes the subject matter according to any of examples 1-10, above.

The first metallic layer on the first side of the electrically isolating substrate is patterned and includes a plurality of metallic segments configured to be electrically isolated from each other. The material deposited onto the first metallic layer forms a plurality of electrical connection pillars. Each one of the plurality of electrical connection pillars is formed on a different one of the plurality of metallic segments. The preceding subject matter of this paragraph characterizes example 12 of the present disclosure, wherein example 12 also includes the subject matter according to any of examples 1-11, above.

The electrical connection pillar includes an electrical power connection pillar. The material deposited onto the first metallic layer further forms a thickened region. The thickened region is electrically connected to the electrical power connection pillar via the first metallic layer. The preceding subject matter of this paragraph characterizes example 13 of the present disclosure, wherein example 13 also includes the subject matter according to any of examples 1-12, above.

The method further includes, after forming the electrical connection pillar, the electrical-component retention feature, and the encapsulant retention feature of the electronics package, positioning the base plate into the electrolyte solution such that a second metallic layer of the base plate, formed on a second side of the electrically isolating substrate opposite the first side of the electrically isolating substrate, directly contacts the electrolyte solution. The second side of the electrically isolating substrate corresponds to a heat-dissipation side of the electronics package. The method additionally includes positioning the deposition anode array into the electrolyte solution such that a second gap is established between the second metallic layer and the plurality of deposition anodes. The method also includes connecting the second metallic layer to the power source. The method additionally includes connecting one or more deposition anodes of the plurality of deposition anodes to the power source. The method also includes transmitting electrical energy from the power source through the one or more deposition anodes of the plurality of deposition anodes, through the electrolyte solution, and to the second metallic layer, such that material is deposited onto the second metallic layer and forms at least a portion of a heat exchange feature of the electronics package. The preceding subject matter of this paragraph characterizes example 14 of the present disclosure, wherein example 14 also includes the subject matter according to any of examples 1-13, above.

The material deposited onto the first metallic layer forms a plurality of electrical connection pillars. The plurality of electrical connection pillars form a pattern of sets of electrical connection pillars. The method further includes splitting the electrically isolating substrate into multiple sub-substrates. A corresponding one of the sets of electrical connection pillars is associated with each one of the multiple sub-substrates. The preceding subject matter of this paragraph characterizes example 15 of the present disclosure, wherein example 15 also includes the subject matter according to any of examples 1-14, above.

The encapsulant retention feature includes at least one surface that is angled or parallel relative to the first side of the electrically isolating substrate and faces the first side of the electrically isolating substrate. The preceding subject matter of this paragraph characterizes example 16 of the present disclosure, wherein example 16 also includes the subject matter according to any of examples 1-15, above.

The encapsulant retention feature includes an overhang. The preceding subject matter of this paragraph characterizes example 17 of the present disclosure, wherein example 17 also includes the subject matter according to example 16, above.

The encapsulant retention feature includes a lateral protrusion. The preceding subject matter of this paragraph characterizes example 18 of the present disclosure, wherein example 18 also includes the subject matter according to any of examples 16-17, above.

The encapsulant retention feature includes a convex surface. The preceding subject matter of this paragraph characterizes example 19 of the present disclosure, wherein example 19 also includes the subject matter according to any of examples 16-18, above.

The encapsulant retention feature includes a concave surface. The preceding subject matter of this paragraph characterizes example 20 of the present disclosure, wherein example 20 also includes the subject matter according to any of examples 16-19, above.

The encapsulant retention feature includes a hole. The preceding subject matter of this paragraph characterizes example 21 of the present disclosure, wherein example 21 also includes the subject matter according to any of examples 16-20, above.

The encapsulant retention feature includes a mesh. The preceding subject matter of this paragraph characterizes example 22 of the present disclosure, wherein example 22 also includes the subject matter according to any of examples 16-21, above.

Further disclosed herein is a method of making an electronics package for an electrical power module, the electrical power module having an encapsulant encapsulating an electrical-component side of the electronics package. The method includes positioning a base plate, including an electrically isolating substrate and a first metallic layer formed on a first side of the electrically isolating substrate, into an electrolyte solution such that the first metallic layer of the base plate directly contacts the electrolyte solution. The first side of the electrically isolating substrate corresponds to a heat-dissipation side of the electronics package, which is opposite the electrical-component side of the electronics package. The method also includes positioning a deposition anode array, including a plurality of deposition anodes, into the electrolyte solution such that a gap is established between the first metallic layer and the plurality of deposition anodes. The method further includes connecting the first metallic layer to a power source. The method additionally includes connecting one or more deposition anodes of the plurality of deposition anodes to the power source. The method also includes transmitting electrical energy from the power source through the one or more deposition anodes of the plurality of deposition anodes, through the electrolyte solution, and to the first metallic layer, such that material is deposited onto the first metallic layer and forms at least a portion of a heat exchange feature of the electronics package. The preceding subject matter of this paragraph characterizes example 23 of the present disclosure.

The heat exchange feature includes a fin. The material deposited onto the first metallic layer forms a plurality of fins. The preceding subject matter of this paragraph characterizes example 24 of the present disclosure, wherein example 24 also includes the subject matter according to example 23, above.

The material deposited onto the first metallic layer further forms at least one of an electrical connection feature or a mechanical connection feature. The preceding subject matter of this paragraph characterizes example 25 of the present disclosure, wherein example 25 also includes the subject matter according to any of examples 23-24, above.

The method, further includes, after forming the heat exchange feature of the electronics package, positioning the base plate into the electrolyte solution such that a second metallic layer of the base plate, formed on a second side of the electrically isolating substrate opposite the first side of the electrically isolating substrate, directly contacts the electrolyte solution. The second side of the electrically isolating substrate corresponds to the electrical-component side of the electronics package. The method additionally includes positioning the deposition anode array into the electrolyte solution such that a second gap is established between the second metallic layer and the plurality of deposition anodes. The method also includes connecting the second metallic layer to the power source. The method further includes connecting one or more deposition anodes of the plurality of deposition anodes to the power source. The method additionally includes transmitting electrical energy from the power source through the one or more deposition anodes of the plurality of deposition anodes, through the electrolyte solution, and to the second metallic layer, such that material is deposited onto the second metallic layer and forms at least one of an electrical connection pillar or an electrical-component retention feature of the electronics package. The preceding subject matter of this paragraph characterizes example 26 of the present disclosure, wherein example 26 also includes the subject matter according to any of examples 23-25, above.

Additionally disclosed herein is an electrical power module. The electrical power module includes a base plate, including an electrically isolating substrate and a first metallic layer formed on a first side of the electrically isolating substrate. The electrical power module also includes electrical connection pillars extending from the first metallic layer. The electrical power module further includes at least one encapsulant retention feature extending from the first metallic layer and including at least one surface that is angled or parallel relative to the first side of the electrically isolating substrate and faces the first side of the electrically isolating substrate. The electrical power module additionally includes at least one electrical component electrically coupled with the metallic layer of the base plate. The electrical power module further includes an encapsulant encapsulating the at least one electrical component, the metallic layer, and the at least one encapsulant retention feature and partially encapsulating the electrical connection pillars. The preceding subject matter of this paragraph characterizes example 27 of the present disclosure.

The base plate further includes a second metallic layer formed on a second side of the electrically isolating substrate that is opposite the first side. The electrical power module further includes at least one heat exchange feature extending from the second metallic layer. The preceding subject matter of this paragraph characterizes example 28 of the present disclosure, wherein example 28 also includes the subject matter according to example 27, above.

The at least one encapsulant retention feature is co-formed with at least one electrical connection pillar of the electrical connection pillars. The preceding subject matter of this paragraph characterizes example 29 of the present disclosure, wherein example 29 also includes the subject matter according to any of examples 27-28, above.

The encapsulant retention feature includes an overhang. The preceding subject matter of this paragraph characterizes example 30 of the present disclosure, wherein example 30 also includes the subject matter according to any of examples 27-29, above.

The encapsulant retention feature includes a lateral protrusion. The preceding subject matter of this paragraph characterizes example 31 of the present disclosure, wherein example 31 also includes the subject matter according to any of examples 27-30, above.

The encapsulant retention feature includes a convex surface. The preceding subject matter of this paragraph characterizes example 32 of the present disclosure, wherein example 32 also includes the subject matter according to any of examples 27-31, above.

The encapsulant retention feature includes a concave surface. The preceding subject matter of this paragraph characterizes example 33 of the present disclosure, wherein example 33 also includes the subject matter according to any of examples 27-32, above.

The encapsulant retention feature includes a hole. The preceding subject matter of this paragraph characterizes example 34 of the present disclosure, wherein example 34 also includes the subject matter according to any of examples 27-33, above.

The encapsulant retention feature includes a mesh. The preceding subject matter of this paragraph characterizes example 35 of the present disclosure, wherein example 35 also includes the subject matter according to any of examples 27-34, above.

Also disclosed herein is an electronics package, for an electrical power module having an encapsulant encapsulating an electrical-component side of the electronics package. The electronics package includes a base plate, including an electrically isolating substrate and a first metallic layer formed on a first side of the electrically isolating substrate and a second metallic layer formed on a second side of the electrically isolating substrate that is opposite the first side. The electronics package also includes electrical connection pillars extending from the first metallic layer. The electronics package further includes at least one encapsulant retention feature extending from the first metallic layer and including at least one surface that is angled or parallel relative to the first side of the electrically isolating substrate and faces the first side of the electrically isolating substrate. The preceding subject matter of this paragraph characterizes example 36 of the present disclosure.

The electronics package further includes at least one heat exchange feature extending from the second metallic layer. The preceding subject matter of this paragraph characterizes example 37 of the present disclosure, wherein example 37 also includes the subject matter according to example 36, above.

The at least one encapsulant retention feature is co-formed with at least one electrical connection pillar of the electrical connection pillars. The preceding subject matter of this paragraph characterizes example 38 of the present disclosure, wherein example 38 also includes the subject matter according to any of examples 36-37, above.

The encapsulant retention feature includes an overhang. The preceding subject matter of this paragraph characterizes example 39 of the present disclosure, wherein example 39 also includes the subject matter according to any of examples 36-38, above.

The encapsulant retention feature includes a lateral protrusion. The preceding subject matter of this paragraph characterizes example 40 of the present disclosure, wherein example 40 also includes the subject matter according to any of examples 36-39, above.

The encapsulant retention feature includes a convex surface. The preceding subject matter of this paragraph characterizes example 41 of the present disclosure, wherein example 41 also includes the subject matter according to any of examples 36-40, above.

The encapsulant retention feature includes a concave surface. The preceding subject matter of this paragraph characterizes example 42 of the present disclosure, wherein example 42 also includes the subject matter according to any of examples 36-41, above.

The encapsulant retention feature includes a hole. The preceding subject matter of this paragraph characterizes example 43 of the present disclosure, wherein example 43 also includes the subject matter according to any of examples 36-42, above.

The encapsulant retention feature includes a mesh. The preceding subject matter of this paragraph characterizes example 44 of the present disclosure, wherein example 44 also includes the subject matter according to any of examples 36-43, above.

The described features, structures, advantages, and/or characteristics of the subject matter of the present disclosure may be combined in any suitable manner in one or more examples and/or implementations. In the following description, numerous specific details are provided to impart a thorough understanding of examples of the subject matter of the present disclosure. One skilled in the relevant art will recognize that the subject matter of the present disclosure may be practiced without one or more of the specific features, details, components, materials, and/or methods of a particular example or implementation. In other instances, additional features and advantages may be recognized in certain examples and/or implementations that may not be present in all examples or implementations. Further, in some instances, well-known structures, materials, or operations are not shown or described in detail to avoid obscuring aspects of the subject matter of the present disclosure. The features and advantages of the subject matter of the present disclosure will become more fully apparent from the following description and appended claims, or may be learned by the practice of the subject matter as set forth hereinafter.

### BRIEF DESCRIPTION OF THE DRAWINGS

In order that the advantages of the subject matter may be more readily understood, a more particular description of the subject matter briefly described above will be rendered by reference to specific examples that are illustrated in the appended drawings. Understanding that these drawings, which are not necessarily drawn to scale, depict only certain examples of the subject matter and are not therefore to be considered to be limiting of its scope, the subject matter will be described and explained with additional specificity and detail through the use of the drawings, in which:

FIG. 1 is a schematic, side elevation view of an electrochemical deposition system for manufacturing a part, according to one or more examples of the present disclosure;

FIG. 2 is a schematic cross-sectional side elevation view of a base plate of an electronics package, according to one or more examples of the present disclosure;

FIG. 3 is a schematic cross-sectional side elevation view of an electronics package, including electrical connection pillars and electrical-component retention features deposited onto the base plate of FIG. 2, according to one or more examples of the present disclosure;

FIG. 4 is a schematic cross-sectional side elevation view of an electronics package, including heat exchange features deposited onto the base plate of FIG. 2, according to one or more examples of the present disclosure;

FIG. 5 is a schematic cross-sectional side elevation view of an electronics package, shown with an electrical component electrically coupled with the base plate of FIG. 2, according to one or more examples of the present disclosure;

FIG. 5A is a schematic cross-sectional side elevation view of an electronics package, shown with an alternative example of an electrical-component retention feature deposited onto the base plate of FIG. 2, according to one or more examples of the present disclosure;

FIG. 6 is a schematic cross-sectional side elevation view of an electrical power module, including the electronics package of FIG. 5, according to one or more examples of the present disclosure;

FIG. 7 is a schematic perspective view of an electronics package, according to one or more examples of the present disclosure;

FIG. 8 is a schematic perspective view of the electronics package of FIG. 7, shown with an electrical component electrically coupled with the base plate of the electronics package, according to one or more examples of the present disclosure;

FIG. 9 is a schematic perspective view of an electrical power module, according to one or more examples of the present disclosure;

FIG. 10 is a schematic perspective view of an array of electronics packages, shown with electrical components electrically coupled with the base plates of electronics packages, according to one or more examples of the present disclosure;

FIG. 11 is a schematic perspective view of an array of electrical power modules, coupled together by a single unit of encapsulant, according to one or more examples of the present disclosure;

FIG. 12 is a schematic perspective cross-sectional view of an electrical power module, with a first encapsulant retention feature, according to one or more examples of the present disclosure;

FIG. 13 is a schematic perspective cross-sectional view of an electrical power module, with a second encapsulant retention feature, according to one or more examples of the present disclosure;

FIG. 14 is a schematic perspective cross-sectional view of an electrical power module, with a third encapsulant retention feature, according to one or more examples of the present disclosure;

FIG. 15 is a schematic perspective cross-sectional view of an electrical power module, with a fourth encapsulant retention feature, according to one or more examples of the present disclosure;

FIG. 16 is a schematic perspective cross-sectional view of an electrical power module, with a fifth encapsulant retention feature, according to one or more examples of the present disclosure;

FIG. 17 is a schematic perspective cross-sectional view of an electrical power module, with a sixth encapsulant retention feature, according to one or more examples of the present disclosure; and

FIG. 18 is a block diagram of a method of making an electronics package, according to one or more examples of the present disclosure.

### DETAILED DESCRIPTION

Reference throughout this specification to “one example,” “an example,” or similar language means that a particular feature, structure, or characteristic described in connection with the example is included in at least one example of the present disclosure. Appearances of the phrases “in one example,” “in an example,” and similar language throughout this specification may, but do not necessarily, all refer to the same example. Similarly, the use of the term “implementation” means an implementation having a particular feature, structure, or characteristic described in connection with one or more examples of the present disclosure, however, absent an express correlation to indicate otherwise, an implementation may be associated with one or more examples.

Electrochemical additive manufacturing utilizes electrochemical reactions to manufacture parts in an additive manufacturing manner. In an electrochemical additive manufacturing process, a metal part is constructed by plating charged metal ions onto a surface of a cathode in an electrolyte solution. This technique relies on placing an electrode (i.e., anode) physically close to the cathode in the presence of a deposition solution (the electrolyte), and energizing the electrode causing charge to flow through the electrode. This creates an electrochemical reduction reaction to occur at the cathode near the electrode and deposition of material on the cathode. Electrochemical additive manufacturing techniques provide distinct advantages over other types of additive manufacturing processes, such as selective laser melting and electron beam melting. Disclosed herein are methods of making electrical power modules and/or electronic packages for electrical power modules, and the corresponding electrical power modules and/or the electronic packages made by such methods.

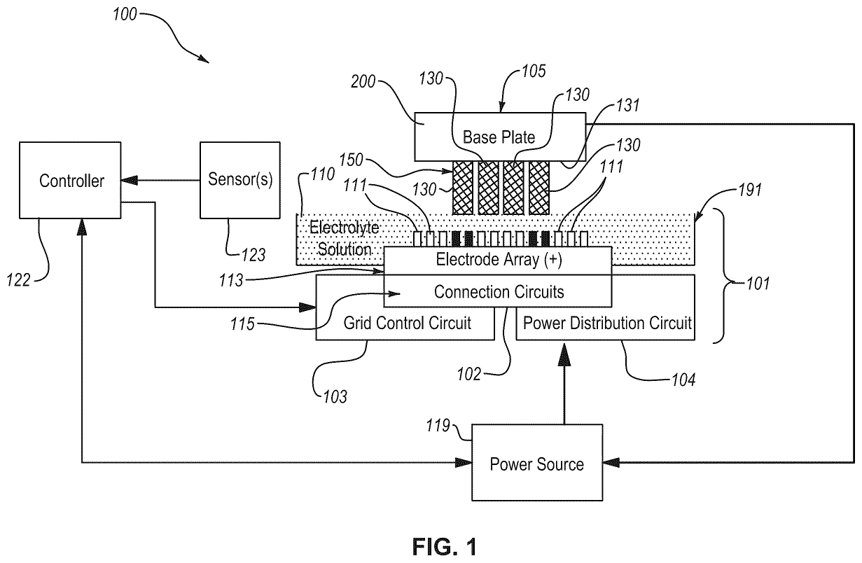

Referring to FIG. 1, according to some examples, an electrochemical deposition system 100 includes a printhead 101 that contains a substrate and at least one electrode 111 (i.e., anode) coupled with the substrate. In certain examples, the printhead 101 contains a plurality of electrodes 111 arranged into an electrode array 113 on the substrate. The printhead 101 further includes at least one connection circuit 115 corresponding with each one of the electrodes 111 of the printhead 101. The at least one connection circuit 115 is integrated into the substrate of the printhead 101. Accordingly, in examples where the printhead 101 contains an electrode array 113, the printhead 101 includes a plurality of connection circuits 115 integrated into the substrate. The connection circuits 115 can be organized into a matrix arrangement, in some examples, thereby supporting a high resolution of electrodes 111. The electrodes 111 of the electrode array 113 are arranged to form a two-dimensional grid in some examples. In FIG. 1, one dimension of the grid is shown with the other dimension of the grid going into and/or coming out of the page.

The printhead 101 further includes a grid control circuit 103 that transmits control signals to the connection circuits 115 to control the amount of electrical current flowing through each one of the electrodes 111 of the electrode array 113. The printhead 101 additionally includes a power distribution circuit 104. The electrical current, supplied to the electrodes 111 via control of the grid control circuit 103, is provided by the power distribution circuit 104, which routes power from an electrical power source 119 of the electrochemical deposition system 100 to the connection circuits 115 and then to the electrodes 111. Although not shown, in some examples, the printhead 101 also includes features, such as insulation layers, that can help protect the electrodes 111 and other features of the printhead 101 from an electrolyte solution 110, as described in more detail below.

The electrochemical deposition system 100 further includes a cathode 105 and the electrolyte solution 110, which can be contained within a partially enclosed container or electrodeposition cell 191. The cathode 105 includes a base plate 200, which can be considered a build plate. In some examples, the electrolyte solution 110 includes one or more of, but not limited to, plating baths, associated with copper, nickel, tin, silver, gold, lead, etc., and which typically include of water, an acid (such as sulfuric acid), metallic salt, and additives (such as levelers, suppressors, surfactants, accelerators, grain refiners, and pH buffers).

The electrochemical deposition system 100 is configured, such as via operation of a controller 122 and sensors 123, to move the printhead 101 relative to the electrolyte solution 110 such that the electrodes 111 of the electrode array 113 are submersed in the electrolyte solution 110. When submersed in the electrolyte solution 110, as shown in FIG. 1, and when the cathode 105 (e.g., the base plate 200) and at least one of the electrodes 111 are connected to an electrical power source 119, and when an electrical current is supplied to the electrodes 111 from the electrical power source 119, an electrical path (or current) is formed through the electrolyte solution 110 from each one of the electrodes 111 to the cathode 105. In such an example, one or more metallic layers of the base plate 200 functions as the cathode of the cathode-anode circuit of the electrochemical deposition system 100. The electrical paths in the electrolyte solution 110 induce electrochemical reactions in the electrolyte solution 110, between the electrodes 111 and a deposition surface 131 (e.g., conductive surface) of the one or more metallic layers of the base plate 200, which results in the formation (e.g., deposition) of material 130 (e.g., layers of metal) on the deposition surface 131 of the base plate 200 at locations corresponding to the locations of the electrodes 111. The material 130, which can be layers of metal, formed by supplying electrical current to multiple electrodes 111 form one or more layers or portions of a part in some examples.

In some examples, the electrodes 111 of the electrode array 113 are densely packed on the substrate of the printhead 101. The area number density or area concentration of the electrodes 111 is proportional to the resolution of the object capable of being formed from the material 130 deposited onto the build plate 102. Generally, the higher the area number density of the electrodes 111, the higher the resolution, detail, and accuracy of the object that can be made from the material 130.

The electrochemical deposition system 100, in some examples, is the same as or similar to the electrochemical deposition systems disclosed in U.S. Pat. No. 10,724,146, issued Jul. 28, 2020, and U.S. Pat. No. 10,914,000, issued Feb. 9, 2021, which are incorporated herein by reference in their entireties.

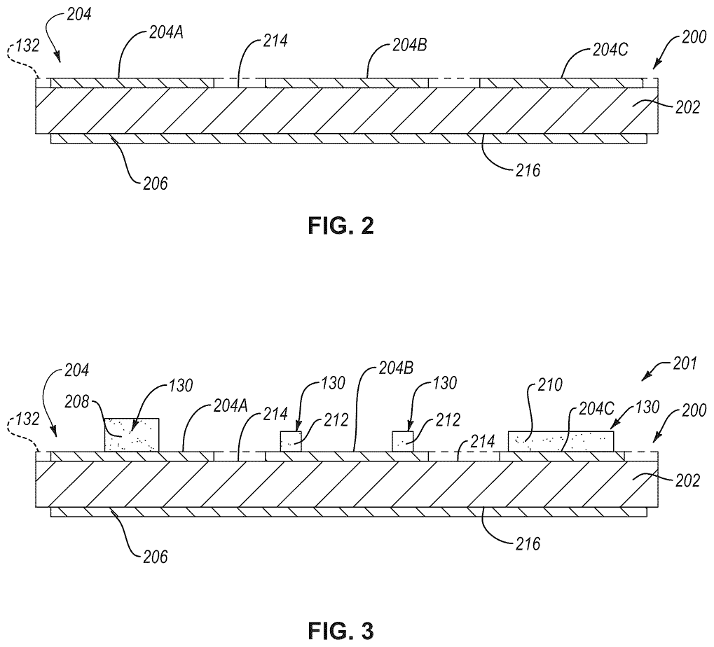

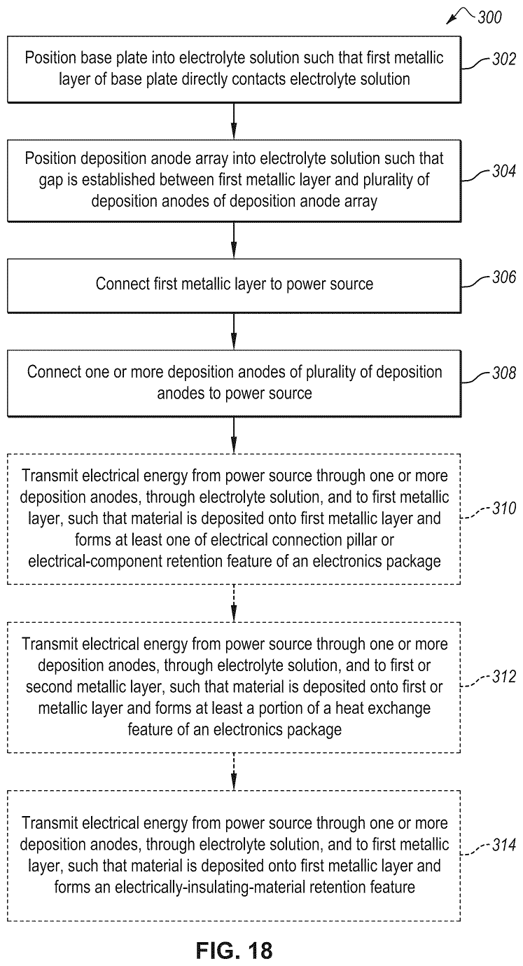

Referring generally to FIG. 18, and particularly to FIGS. 2-4, according to some examples, a method 300 of making an electronics package 201 is shown. Referring to FIGS. 2 and 18, the method 300 includes (block 302) positioning a base plate 200 into an electrolyte solution 110 of an electrochemical deposition system, such as the electrochemical deposition system 100 of FIG. 1. As shown in FIG. 2, the base plate 200 includes an electrically isolating substrate 202 (e.g., tile) and a first metallic layer 204 formed on a first side 214 of the electrically isolating substrate 202. The first side 214 of the electrically isolating substrate 202 corresponds to an electrical-component side of the electronics package 201. The electrically isolating substrate 202 is made of an electrically insulative or non-conductive material, such as, for example, plastics, ceramics, woven glass embedded in epoxy, and the like. In some examples, the electrically isolating substrate 202 is made of a ceramic material used in the power electronics industry, such as, but not limited to, aluminum oxide, aluminum nitride, silicon nitride, and beryllium oxide. In certain examples, the electrically isolating substrate 202 can be an insulated metal substrate (IMS). According to some examples, the electrically isolating substrate 202 includes one or more coatings, such as aluminum oxy-nitride coatings. Alternatively, the electrically isolating substrate 202 can be made of a semiconductor material. The electrically isolating substrate 202 can be a rigid substrate or a flexible substrate. The first metallic layer 204 includes one or more conductive features, such as an electrical pad or an electrical trace, deposited (e.g., attached, printed, applied, painted, etc.) onto the electrically isolating substrate 202. In some examples, the base plate 200 is a printed circuit board (e.g., single layer or multi-layer), an insulated metal substrate, a ceramic substrate, or the like. According to block 302 of the method 300, the base plate 200 is positioned into the electrolyte solution 110 such that the first metallic layer 204 of the base plate 200 directly contacts the electrolyte solution 110.

Referring again to FIG. 18, the method 300 additionally includes (block 304) positioning a deposition anode array 113, having a plurality of deposition anodes (e.g., electrodes 111), into the electrolyte solution 110 such that a gap is established between the first metallic layer 204 of the base plate 200 and the plurality of deposition anodes. The method 300 then includes (block 306) connecting the first metallic layer 204 to a power source 119 and (block 308) connecting one or more deposition anodes of the plurality of deposition anodes to the power source 119.

According to some examples, and referring to FIGS. 3 and 18, the method 300 further includes (block 310) transmitting electrical energy from the power source 119 through the one or more deposition anodes of the plurality of deposition anodes, through the electrolyte solution 110, and to the first metallic layer 204, such that material 130 is deposited onto the first metallic layer 204 and forms at least one of an electrical connection pillar (e.g., one or more of an electrical signal connection pillar 208 or an electrical power connection pillar 210) or an electrical-component retention feature 212 of the electronics package 201. The term “pillar” in this context can be used interchangeably with “structure” or other similar feature. In one example, at block 310, the material 130 only forms at least one electrical connection pillar. According to another example, at block 310, the material 130 only forms at least one electrical-component retention feature 212. In yet another example, the material 130 forms both at least one electrical connection pillar and at least one electrical-component retention feature 212.

In some examples, the first metallic layer 204 of the base plate 200, which is on the first side 214 of the electrically isolating substrate 202, includes multiple metallic segments that are eventually electrically isolated from each other (e.g., electrically isolated when the electrical power module is operational). In some examples, to facilitate manufacturing of the electronics package 201 using electrochemical deposition, as shown in FIGS. 2 and 3, a seed layer 132 can be applied onto the electrically isolating substrate 202. The seed layer 132, which is shown in dashed line in FIGS. 2 and 3, can be a substantially uniform layer of metallic material applied onto the first side 214 of the electrically isolating substrate 202. After the material 130 is deposited onto the seed layer 132 at designated locations corresponding with the locations of the metallic segments, the portions of the seed layer 132 between the locations of the metallic segments can be removed (e.g., chemically etched away). The non-removed or non-etched portions of the seed layer 132 then form the multiple metallic segments. Using a seed layer helps to simplify the steps necessary to electrically connect metallic material on the electrically isolating substrate 202 to the plurality of electrodes 111 of the electrode array 113. However, it is recognized that in some examples, the multiple metallic segments can be pre-formed prior to depositing the material 130 and each one of the multiple metallic segments can be individually and separately electrically connected to the plurality of electrodes 111 of the electrode array 113.

The multiple metallic segments can form a pattern of metallic segments, such that the first metallic layer 204 can be considered a patterned layer. For example, referring to FIGS. 2 and 3, the first metallic layer 204 includes a first metallic segment 204A, a second metallic segment 204B, and a third metallic segment 204C. Although three metallic segments are shown, in other examples, the base plate 200 includes more or fewer than three metallic segments.

When electrical connection pillars are formed at block 310, in some examples, the deposition anodes, corresponding to the locations of the metallic segments, are selectively activated such that each one of electrical connection pillars is formed on a respective one of multiple metallic segments. In some examples, each one of the electrical connection pillars is formed on a different one of the multiple metallic segments. For example, in FIG. 3, the material 130 deposited onto the first metallic segment 204A forms an electrical signal connection pillar 208 and the material 130 deposited onto the third metallic segment 204C forms an electrical power connection pillar 208. Because the electrical signal connection pillar 208 is formed on a different metallic segment than the electrical power connection pillar 210, the electrical signal connection pillar 208 is electrically isolated from the electrical power connection pillar 210.

In some examples, the deposition of the material 130 is controlled such that each one of the electrical connection pillars has a desired size and shape. According to certain examples, the size and/or shape of the electrical signal connection pillar 208 is different from that of the electrical power connection pillar 210. For example, in one implementation, the electrical signal connection pillar 208 has a cylindrical shape and the electrical power connection pillar 210 has a rectangular shape. In certain implementations, the height of the electrical signal connection pillar 208 is the same as the height of the electrical power connection pillar 210 (i.e., the electrical signal connection pillar 208 extends away from the first side 214 of the electrically isolating substrate 202 a distance the same as that of the electrical power connection pillar 210). The electrical signal connection pillar 208 is primarily configured to receive and transmit electrical signals associated with the control of electrical components. In contrast, the electrical power connection pillar 210 is primarily configured to receive electrical power associated with powering electrical components of the electrical power module 230 and/or electrical devices electrically coupled to the electrical power module 230. Although electrical power connections can be considered a type of electrical signal connection, because the electrical power connection pillar 210 is configured to primarily receive and/or transmit raw electrical power, it is defined herein as an electrical power connection pillar because it functions differently than the electrical signal connection pillar 208. As used herein, electrical power can be AC, DC, modulated AC, and the like. In some examples, electrical power can be high-voltage electrical power (e.g., between 400 volts and 800 volts) and/or high-current electrical power (e.g., greater than 100 amps). According to certain examples, one or more of the electrical connections (e.g., electrical power connection pillars) of the electronics package 201 can be connected to power and/or ground planes, such as those employed on printed circuit boards.

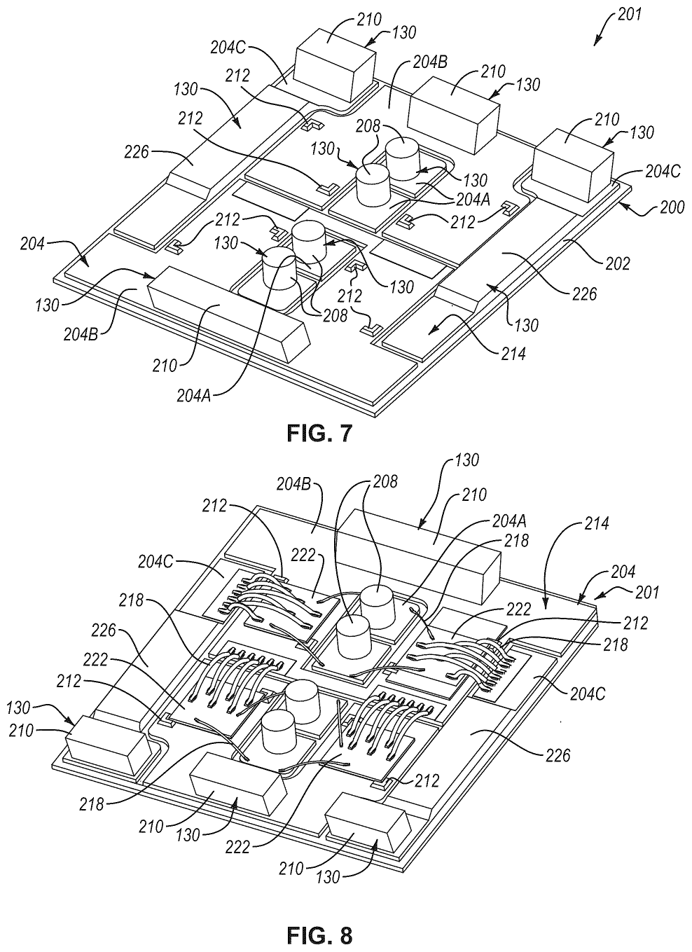

Referring again to FIG. 3, when electrical-component retention features 212 are formed at block 310, in some examples, the deposition anodes, corresponding to the locations of a certain one or more of the metallic segments, are selectively activated such that electrical-component retention features 212 are formed on the certain one or more of the multiple metallic segments. In some examples, multiple electrical-component retention features 212 are formed on the same metallic segments. Moreover, according to certain examples, electrical-component retention features 212 are formed on the same metallic segment as an electrical connection pillar. For example, in FIG. 3, the material 130 deposited onto the second metallic segment 204B forms multiple electrical-component retention features 212. As another example, in FIG. 7, multiple electrical-component retention features 212 and an electrical power connection pillar 210 are formed on the same second metallic segment 204B.

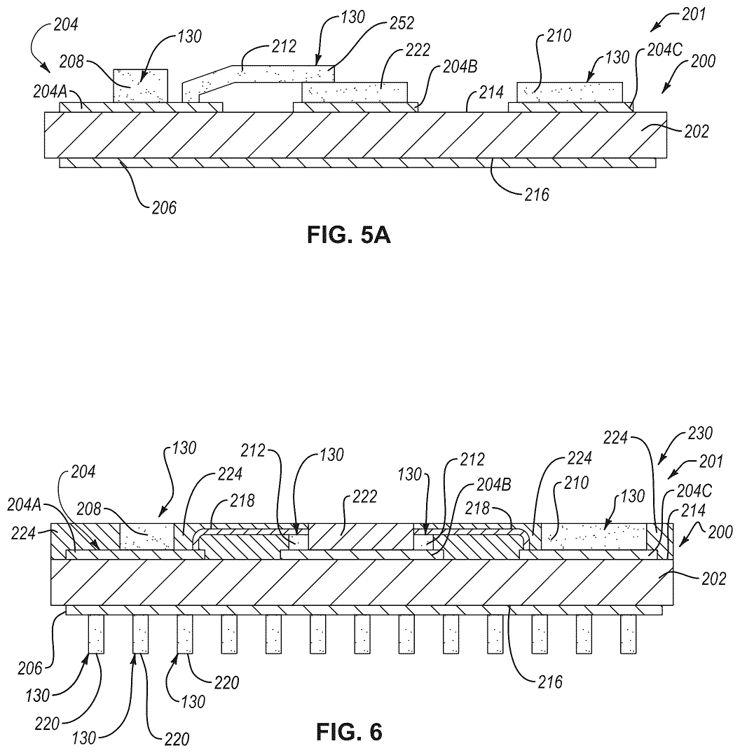

Each one of the electrical-component retention features 212 is configured to at least partially receive and retain one or more electrical components 222 of the electrical power module 230. The electrical-component retention feature 212 can act as a guide for properly positioning or aligning an electrical component 222 and/or retaining the electrical component 222. In one example, as shown in FIGS. 5, 7, and 8, each one of the electrical-component retention features 212 is configured to receive and engage a corner of a corresponding electrical component 222. Referring to FIG. 5, as shown in dashed line, in certain examples, the material 130 can be deposited so that the electrical-component retention feature 212 has an overhang 250 configured to extend over an electrical component 222, thus helping to retain the electrical component 222. As shown in FIG. 5A, in some examples, the material 130 forming the electrical-component retention feature 212 can be deposited to extend from one metallic segment to another metallic segment. In these examples, the electrical-component retention feature 212 can provide retention of the electrical component 222, as well as provide an electrical contact 252 between the electrical component 222 and the metallic segment from which it extends.

As shown in FIG. 7, in some examples, at block 310 of the method 300, the material 130 deposited onto the first metallic layer 204 also forms a thickened region 226. In some examples, the thickened region 226 is formed onto the same metallic segment (e.g., the third metallic segment 204C in FIG. 7) that at least one electrical power connection pillar 210 is formed. Accordingly, the thickened region 226 is electrically connected to the electrical power connection pillar 210 via the first metallic layer 204. The added thickness of the thickened region 226 can help to accommodate the flow or isolation of high-voltage power (e.g., between 400 volts and 800 volts) and/or high-current power (e.g., greater than 100 amps).

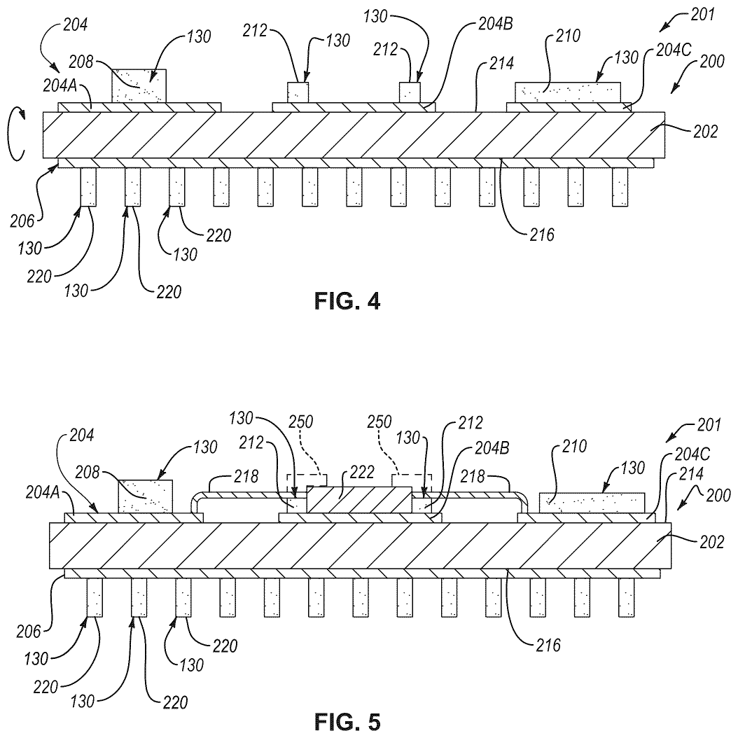

Referring to FIGS. 4 and 18, in some examples, in addition to, or instead of, block 310, the method 300 includes (block 312) transmitting electrical energy from the power source 119 through the one or more deposition anodes, through the electrolyte solution 110, and to the first metallic layer 204 or a second metallic layer 206 of the base plate 200 so that the material 130 being deposited onto the first metallic layer 204 or the second metallic layer 206 form at least a portion of a heat exchange feature 220 of the electronics package 201. The second metallic layer 206 is formed on a second side 216 of the electrically isolating substrate 202, which is opposite the first side 214 of the electrically isolating substrate 202. The second side 216 of the electrically isolating substrate 202 can correspond to a heat-dissipation side of the electronics package 201. In certain examples, the second metallic layer 206 is a non-patterned or non-segmented layer of metallic material. The metallic material of the first metallic layer 204 and the second metallic layer 206 can be any of various types of metallic materials, such as copper, germanium, titanium, and the like, and can be applied to the electrically isolating substrate 202 using any of various techniques, such as sputtering, dip coating, thermal deposition, atomic layer deposition, masking, plating, and the like.

In one example, the portion of the heat exchange feature 220 is deposited onto the second metallic layer 206 before or after electrical connection pillars and/or electrical-component retention features are formed on the first metallic layer 204. In such an example, block 312 of the method 300 includes (i) positioning the base plate 200 into the electrolyte solution 110 such that the second metallic layer 206 of the base plate 200 directly contacts the electrolyte solution 110; (ii) positioning the deposition anode array 113 into the electrolyte solution 110 such that a second gap is established between the second metallic layer 206 and the plurality of deposition anodes; (iii) connecting the second metallic layer 206 to the power source 119; and (iv) connecting one or more deposition anodes of the plurality of deposition anodes to the power source 119. This leads to block 312 of the method 300, which results in the material 130 being deposited onto the second metallic layer 206 to form at least the portion of the heat exchange feature 220 of the electronics package 201. In some examples, after block 310 or block 312 is performed, the method 300 can include flipping the base plate 200 (see, e.g., the rotational arrow in FIG. 4) so that the other of block 310 and block 312 can be performed using the same electrolyte solution 110. However, in other examples, different electrolyte solutions 110, and even different electrochemical deposition systems, are used to perform block 310 and block 312, respectively.

The heat exchange feature 220 can form part of a thermal component, such as a heatsink, cold plate, or vapor chamber of the electrical power module 230. The second metallic layer 206 can form a base of the heatsink and the heat exchange feature 220 includes one or more structures configured to facilitate the transfer (e.g., dissipation or receipt) of heat. As shown in FIG. 4, the electronics package 201 can include multiple heat exchange features 220 where each one of the multiple heat exchange features 220 is at least partially formed from the material 130 deposited onto the second metallic layer 206. In one example, each one of the heat exchange features 150 includes one or more elongated fins extending uprightly and lengthwise from the second metallic layer 206, or the first metallic layer 204 if applicable. The elongated fins can be spaced apart from each other across the second metallic layer 206, such as shown in FIG. 4. Moreover, the elongated fins can have any of various shapes that promote the transfer of heat, such as shapes that optimize the surface area per unit length of the elongated fins.

Referring to FIGS. 5 and 8, and according to some examples, a method of making the electrical power module 230 includes mounting and electrically connecting at least one electrical component 222 to the electronics package 201. In some examples, mounting an electrical component 222 can include engaging the electrical component 222 with one or more electrical-component retention features 212 formed on a metallic segment of the first metallic layer 204 (e.g., the second metallic segment 204B) to properly align and/or retain the electrical component 222 on the first metallic layer 204. Various other mounting and retention techniques can also be used, such as adhering, bonding, welding, and the like.

The electrical component 222 can be electrically connected to the electronics package 201 by forming electrical connections between the electrical component 222 and the metallic segment on which it is directly mounted and/or between the electrical component 222 and one or more other metallic segments to which the electrical component 222 is not directly mounted. The electrical connections with other metallic segments can be established with wires 218 (e.g., via a wire bonding process) that span from the electrical component 222 to one or more adjacent metallic segments. For example, in the illustrated examples, the method includes establishing an electrical connection between the electrical component 222 and an electrical power connection pillar 210, to receive electrical power from or provide electrical power to the electrical power connection pillar 210, via one or more wires 218 that span from the electrical component 222 to the third metallic segment 204C. Similarly, in the illustrated examples, the method includes establishing an electrical connection between the electrical component 222 and an electrical signal connection pillar 208, to receive electrical signals from or provide electrical signals to the electrical signal connection pillar 208, via one or more wires 218 that span from the electrical component 222 to the first metallic segment 204A.

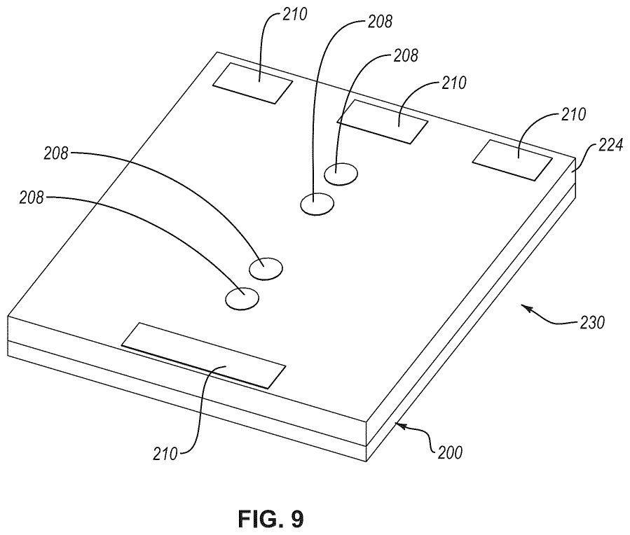

Referring to FIGS. 6 and 9, after mounting and electrically connecting the electrical components 222 to the electronics package 201, the method of making the electrical power module 230 further includes encapsulating the electrical-component side of the electronics package 201 with an encapsulant 224. As defined herein, encapsulating the electrical-component side of the electronics package 201 means fully encapsulating the electrical components 222 and the wires 218, and partially encapsulating the electrical connection pillars of the electronics package 201. Partial encapsulation of the electrical connection pillars includes encapsulating the sides and base of the electrical connection pillars, but leaving exposed a top portion or top surface of the electrical connection pillars. Exposing the top portion or top surface of the electrical connection pillars enables an electrical connection to be established with the electrical connection pillars from outside or external to the electrical power module 230. In one example, the encapsulant 224, in liquid form is poured or potted onto the electrical-component side of the electronics package 201 and allowed to harden or cure. According to certain examples, encapsulation is done using injection molding, low-pressure molding, medium-pressure encapsulation, and/or encapsulation foam molding.

The full encapsulation of the electrical components, and partial encapsulation of the electrical connection pillars, by the encapsulant 224 helps to mechanically strengthen, retain, and protect the electrical connections between the electrical components 222 and the electronics package 201 during use of the electrical power module 230. The encapsulant 224 bonds to the electrical components 222, the wires 218, the electrical connection pillars, and the first side 214 of the base plate 200, which mechanically joins the components together and helps distribute impacts loads. The encapsulant 224 can be any of various electrically non-conductive or electrically-insulating materials, such as, but not limited to, epoxy resin (e.g., epoxy molding compound), plastics, plasters, and the like.

Some conventional electrical devices, such as conventional electrical power modules, being a molded part can be susceptible to various failure modes during use. For example, the encapsulant of some conventional electrical power modules are susceptible to cracking and/or debonding (e.g., connection separation) from the underlying electrical components. In some instances, the bond strength between the encapsulant and the electrical components, such as electrical connection pillars, is not strong enough to withstand certain debonding forces, and the material separates from the electrical components.

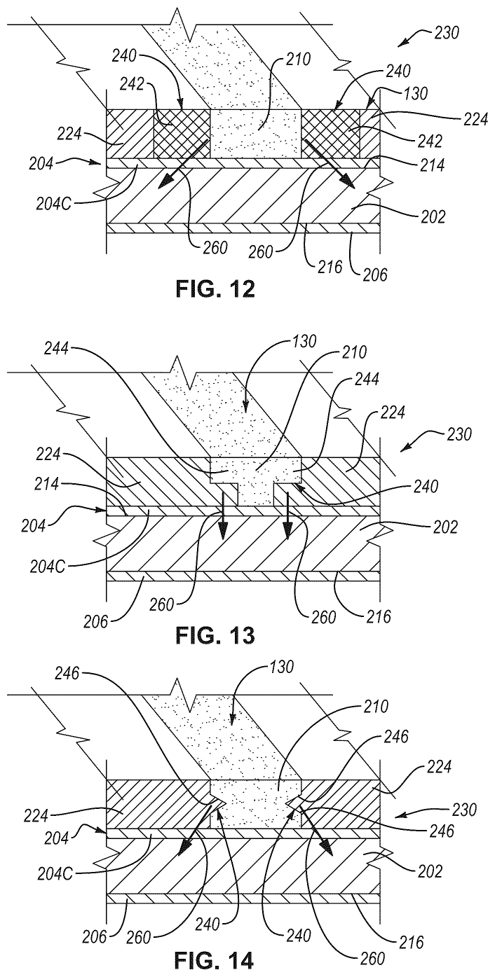

According to the present disclosure, in some examples, as shown in FIGS. 12-17, the method 300 for making the electronics package 201 additionally, or alternatively, includes (block 314) transmitting electrical energy from the power source 119 through the one or more deposition anodes, through the electrolyte solution 110, and to the first metallic layer 204 of the base plate 200 so that the material 130 being deposited onto the first metallic layer 204 forms one or more encapsulant retention features 240 of the electronics package 201. The encapsulant retention features 240 are configured to interact with the encapsulant 224 and to help retain the encapsulant 224 on the electrical-component side of the electronics package 201. More specifically, the encapsulant retention features 240 help to increase the bond and/or retention strength between the encapsulant 224 and the electronics package 201, by increasing the bond area and/or providing an upper barrier/stop. Put another way, the encapsulant retention features 240 help prevent the encapsulant 224 from separating from the electronics package 201 by increasing the pull-off force necessary to do so.

According to certain examples, the encapsulant retention features 240 includes surfaces that at least partially overhang the encapsulant 224 and act as an upper barrier or stop to help prevent the encapsulant 224 from separating upwardly away from the electronics package 201. In some examples, each one of the encapsulant retention features 240 includes at least one surface that is angled or parallel relative to the first side 214 of the electrically isolating substrate 202 of the base plate 200 and faces the first side 214 of the electrically isolating substrate 202. As defined herein, the at least one surface faces the first side 214 when a vector 260 perpendicular to the at least one surface intersects the first side 214 of the electrically isolating substrate 202 or a hypothetical plane that is co-planar with the first side 214 of the electrically isolating substrate 202. Due to the small size of the electrical power module 230 and the overhanging nature of the encapsulant retention features 240, the formation of the encapsulant retention features 240 can be difficult or impossible for conventional formation techniques. However, the electrochemical deposition system and associated process disclosed herein are particularly suitable for forming the encapsulant retention features 240 on the first metallic layer 204.

According to some examples, at block 314 of the method 300, at least one of the encapsulant retention features 240 is co-formed with an electrical connection pillar. For example, one or more encapsulant retention features 240 is an extension or feature of (formed monolithically with) an electrical connection pillar. Referring to FIG. 12, in one example, the encapsulant retention feature 240 is a mesh 242 that is co-formed with or is an extension of an electrical connection pillar (e.g., the electrical power connection pillar 210 in FIG. 12). The mesh 242 is formed by continuously depositing the material 130 to form both the mesh 242 and the electrical connection pillar as a one-piece monolithic structure. In some examples, a mesh 242 is formed on both sides of an electrical connection pillar to effectively flank opposing sides of the electrical connection pillar.

The mesh 242 can be a structure made of interlaced strands of the material 130, which collectively forms a weblike pattern or construction. At least some of the strands of the mesh 242 are angled or parallel relative to the first side 214 of the electrically isolating substrate 202 and face the first side 214 of the electrically isolating substrate 202, as defined above. Accordingly, when the encapsulant 224 is applied onto the electrical-component side of the electronics package 201, the encapsulant 224 infuses with or fills the open spaces of the mesh 242. When hardened, the encapsulant 224 interacts with the strands of the mesh 242, which help to restrict pull-off of the encapsulant 224 from the electronics package 201.

Referring to FIG. 13, in one example, the encapsulant retention feature 240 is an overhang 244 that is co-formed with or is an extension of an electrical connection pillar (e.g., the electrical power connection pillar 210 in FIG. 13). The overhang 244 is formed by continuously depositing the material 130 to form both the overhang 244 and the electrical connection pillar as a one-piece monolithic structure. In some examples, an overhang 244 is formed on both sides of an electrical connection pillar to effectively flank opposing sides of the electrical connection pillar. The overhang 244 extends laterally away from the electrical connection pillar at a top portion of the electrical connection pillar (thus forming a “T” shape), such that a gap is defined between the overhang 244 and the first metallic layer 204. When the encapsulant 224 is applied onto the electrical-component side of the electronics package 201, the encapsulant 224 fills the gap as shown in FIG. 13. When hardened, the encapsulant 224 interacts with the underside surface of the overhang 244, which helps to restrict pull-off of the encapsulant 224 from the electronics package 201.

Referring to FIG. 14, in one example, the encapsulant retention feature 240 is a concave surface 246 or notch formed into an electrical connection pillar (e.g., the electrical power connection pillar 210 in FIG. 14). In some examples, a concave surface 246 is formed on both sides of an electrical connection pillar (thus forming an “I” shape). The concave surface 246 can extend laterally into a side of the electrical connection pillar at any of various locations along a height of the electrical connection pillar. When the encapsulant 224 is applied onto the electrical-component side of the electronics package 201, the encapsulant 224 fills the space in the electrical connection pillar defined by the concave surface 246, as shown in FIG. 14. When hardened, the encapsulant 224 interacts with an upper portion of the concave surface 246, which helps to restrict pull-off of the encapsulant 224 from the electronics package 201.

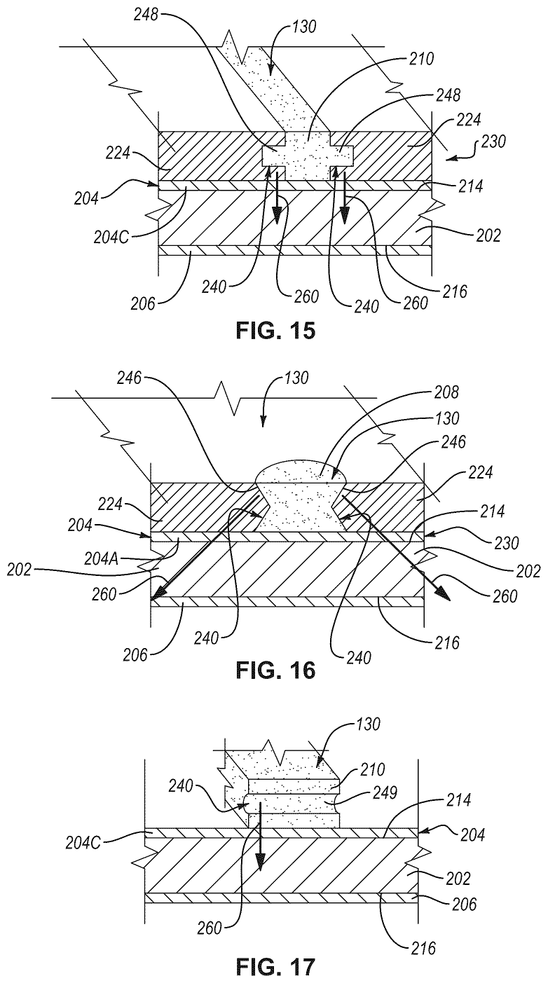

Referring to FIG. 15, in one example, the encapsulant retention feature 240 is a lateral protrusion 248 (e.g., a convex surface) that is co-formed with or is an extension of an electrical connection pillar (e.g., the electrical power connection pillar 210 in FIG. 14). The lateral protrusion 248 is formed by continuously depositing the material 130 to form both the lateral protrusion 248 and the electrical connection pillar as a one-piece monolithic structure. In some examples, a lateral protrusion 248 is formed on both sides of an electrical connection pillar to effectively flank opposing sides of the electrical connection pillar. The lateral protrusion 248 is similar to the overhang 244 because it extends laterally away from the electrical connection pillar. However, unlike the overhang 244, which extends from a top portion of the electrical connection pillar, the lateral protrusion 248 extends from a middle or lower portion of the electrical connection pillar (thus forming a “+” shape). A gap is defined between the lateral protrusion 248 and the first metallic layer 204. When the encapsulant 224 is applied onto the electrical-component side of the electronics package 201, the encapsulant 224 fills the gap, as shown in FIG. 15. When hardened, the encapsulant 224 interacts with the underside surface of the lateral protrusion 248, which helps to restrict pull-off of the encapsulant 224 from the electronics package 201.

Referring to FIG. 16, in one example, the encapsulant retention feature 240 is a concave surface 246 or notch formed into an electrical connection pillar. Accordingly, the concave surface 246 of FIG. 16 is similar to the concave surface 246 of FIG. 14. However, in the illustrated examples, the concave surface 246 of FIG. 14 is formed into a rectangular-shaped electrical power connection pillar 210, while the concave surface 246 of FIG. 16 is formed into a cylindrical-shaped electrical signal connection pillar 208. Moreover, the concave surface 246 in FIG. 16 has an annular shape that extends about an entire circumference of the electrical signal connection pillar 208. In other words, the cylindrical-shaped electrical signal connection pillar 208 has a “>” shaped radial cross-section. Other radial cross-sectional shapes, such as “<”, “/”, “L”, “(“,“)”, “\”, and the like, can be employed. Although the concave surface 246 is shown to have a continuous annular shape about a cylindrical structure, it is recognized that the concave surface 246 could have a continuous shape about any of various structures. Moreover, in some examples, other types of encapsulant retention features 240, such as the mesh 242, the overhang 244, the lateral protrusion 248, and the like, continuously extend around an electrical connection pillar.

Referring to FIG. 17, in one example, the encapsulant retention feature 240 is a hole 249 or aperture formed into an electrical connection pillar (e.g., the electrical power connection pillar 210 in FIG. 17). In some examples, the hole 249 is a through-hole that extends from one side of an electrical connection pillar to another side. The hole 249 can extend through an electrical connection pillar at any of various locations along a height of the electrical connection pillar. Moreover, the hole 249, although shown parallel to the first side 214 of the electrically isolating substrate, can be angled at any of various angles, other than 90-degrees, relative to the first side 214. When the encapsulant 224 is applied onto the electrical-component side of the electronics package 201, the encapsulant 224 fills the hole 249. When hardened, the encapsulant 224 interacts with an upper surface of the hole 249, which helps to restrict pull-off of the encapsulant 224 from the electronics package 201.

According to some examples, the method 300 can include steps for forming any of various electrical connection features or mechanical connection features, other than those disclosed above, by depositing the material 130 onto a metallic layer of the base plate 200. For example, the method 300 can be used to form mechanical connection features that help facilitate the attachment of the electrical power module 230 to another component or structure. Similarly, other electrical connection features can be forms to facilitate the electrical coupling of the electrical power module 230 to another component or the electrical coupling of components of the electrical power module 230.

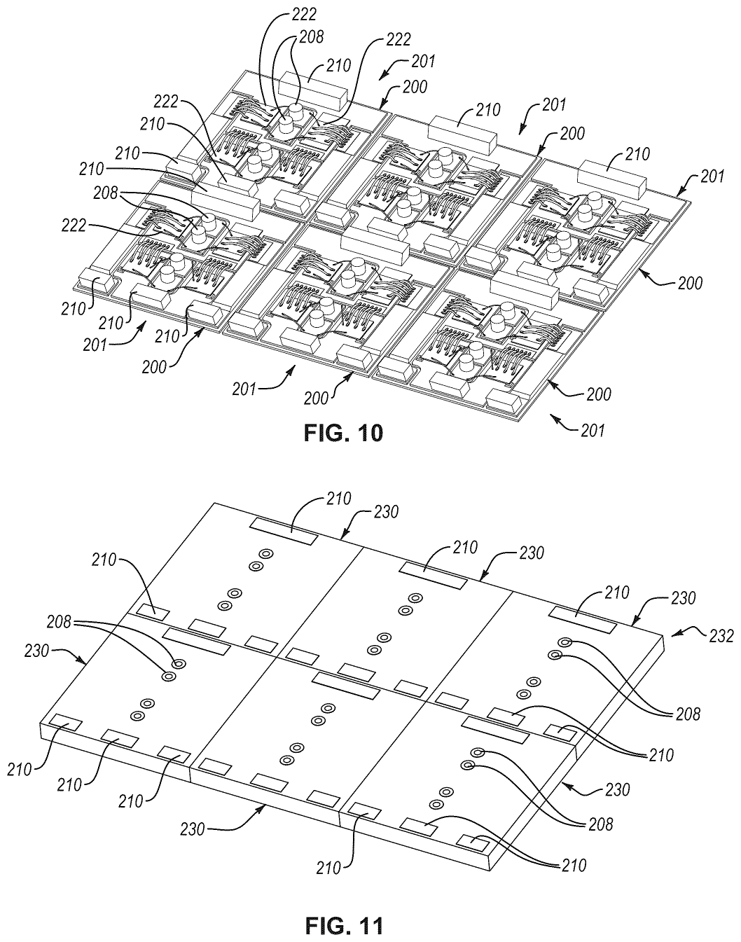

The electrochemical deposition system and method of the present disclosure are particularly suitable for forming multiple electronics packages 201 using a panelization technique. Referring to FIGS. 10 and 11, the method 300 can be used to form patterns of electrical connection pillars, electrical-component retention features, heat exchange features, and/or encapsulant retention features onto the same base plate 200 or multiple base plates 200 arranged in close proximity in a co-planar arrangement. In some examples, the patterns are identical and repeating. However, in other examples, the patterns are not identical. After forming the features with the material 130, and before or after encapsulant is applied, if formed on the same base plate 200, the base plate 200, and encapsulant 224 if applicable, is split into multiple sub-plates or sub-packages. Alternatively, after forming the features with the material 130, if formed on multiple base plates 200, and when in the co-planar arrangement, encapsulant 224 can be applied onto the electrical-component side of all the electronics packages 201 at the same time. Following hardening, the encapsulant 224 can be cut through along lines associated with the boundaries between adjacent ones of the electronics packages 201 to split the multi-module structure 232 into multiple modules, thus creating multiple, isolated electrical power modules 230.

Instead of depositing the material 130 using an electrochemical deposition technique, which is preferred as discussed above, in some less preferred examples, the material 130 can be deposited using a laser powder bed fusion technique. The same type of features can be formed. However, due to the relatively high material temperatures reached when implementing a laser powder bed fusion technique, the features can warp as they cool. Moreover, features formed using laser powder bed fusion techniques are less precise and have poorer surface finishes than features formed using the above-described electrochemical deposition techniques.

In the above description, certain terms may be used such as “up,” “down,” “upper,” “lower,” “horizontal,” “vertical,” “left,” “right,” “over,” “under” and the like. These terms are used, where applicable, to provide some clarity of description when dealing with relative relationships. But, these terms are not intended to imply absolute relationships, positions, and/or orientations. For example, with respect to an object, an “upper” surface can become a “lower” surface simply by turning the object over. Nevertheless, it is still the same object. Further, the terms “including,” “comprising,” “having,” and variations thereof mean “including but not limited to” unless expressly specified otherwise. An enumerated listing of items does not imply that any or all of the items are mutually exclusive and/or mutually inclusive, unless expressly specified otherwise. The terms “a,” “an,” and “the” also refer to “one or more” unless expressly specified otherwise. Further, the term “plurality” can be defined as “at least two. ” Moreover, unless otherwise noted, as defined herein a plurality of particular features does not necessarily mean every particular feature of an entire set or class of the particular features.

Additionally, instances in this specification where one element is “coupled” to another element can include direct and indirect coupling. Direct coupling can be defined as one element coupled to and in some contact with another element. Indirect coupling can be defined as coupling between two elements not in direct contact with each other, but having one or more additional elements between the coupled elements. Further, as used herein, securing one element to another element can include direct securing and indirect securing. Additionally, as used herein, “adjacent” does not necessarily denote contact. For example, one element can be adjacent to another element without being in contact with that element.

As used herein, the phrase “at least one of”, when used with a list of items, means different combinations of one or more of the listed items may be used and only one of the items in the list may be needed. The item may be a particular object, thing, or category. In other words, “at least one of” means any combination of items or number of items may be used from the list, but not all of the items in the list may be required. For example, “at least one of item A, item B, and item C” may mean item A; item A and item B; item B; item A, item B, and item C; or item B and item C. In some cases, “at least one of item A, item B, and item C” may mean, for example, without limitation, two of item A, one of item B, and ten of item C; four of item B and seven of item C; or some other suitable combination.

Unless otherwise indicated, the terms “first,” “second,” etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third”or higher-numbered item.

As used herein, a system, apparatus, structure, article, element, component, or hardware “configured to” perform a specified function is indeed capable of performing the specified function without any alteration, rather than merely having potential to perform the specified function after further modification. In other words, the system, apparatus, structure, article, element, component, or hardware “configured to” perform a specified function is specifically selected, created, implemented, utilized, programmed, and/or designed for the purpose of performing the specified function. As used herein, “configured to” denotes existing characteristics of a system, apparatus, structure, article, element, component, or hardware which enable the system, apparatus, structure, article, element, component, or hardware to perform the specified function without further modification. For purposes of this disclosure, a system, apparatus, structure, article, element, component, or hardware described as being “configured to” perform a particular function may additionally or alternatively be described as being “adapted to”and/or as being “operative to”perform that function.

The term “about” or “substantially” or “approximately” in some embodiments, is defined to mean within +/−5% of a given value, however in additional embodiments any disclosure of “about” or “substantially” or “approximately” may be further narrowed and claimed to mean within +/−4% of a given value, within +/−3% of a given value, within +/−2% of a given value, within +/−1% of a given value, or the exact given value. Further, when at least two values of a variable are disclosed, such disclosure is specifically intended to include the range between the two values regardless of whether they are disclosed with respect to separate embodiments or examples, and specifically intended to include the range of at least the smaller of the two values and/or no more than the larger of the two values. Additionally, when at least three values of a variable are disclosed, such disclosure is specifically intended to include the range between any two of the values regardless of whether they are disclosed with respect to separate embodiments or examples, and specifically intended to include the range of at least the A value and/or no more than the B value, where A may be any of the disclosed values other than the largest disclosed value, and B may be any of the disclosed values other than the smallest disclosed value.

The schematic flow chart diagram included herein is generally set forth as a logical flow chart diagram. As such, the depicted order and labeled steps are indicative of one example of the presented method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagrams, they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not adhere to the order of the corresponding steps shown. Blocks represented by dashed lines indicate alternative operations and/or portions thereof. Dashed lines, if any, connecting the various blocks represent alternative dependencies of the operations or portions thereof. It will be understood that not all dependencies among the various disclosed operations are necessarily represented.

The present subject matter may be embodied in other specific forms without departing from its spirit or essential characteristics. The described examples are to be considered in all respects only as illustrative and not restrictive. All changes which come within the meaning and range of equivalency of the claims are to be embraced within their scope.

What is claimed is:

1. An electrical power module, comprising:
a base plate, comprising an electrically isolating substrate and a first metallic layer formed on a first side of the electrically isolating substrate;
electrical connection pillars extending from the first metallic layer;
at least one encapsulant retention feature extending from the first metallic layer and comprising at least one surface that is angled or parallel relative to the first side of the electrically isolating substrate and faces the first side of the electrically isolating substrate;
at least one electrical component electrically coupled with the metallic layer of the base plate; and
an encapsulant encapsulating the at least one electrical component, the metallic layer, and the at least one encapsulant retention feature and partially encapsulating the electrical connection pillars.

2. The electrical power module according to claim 1, wherein:
the base plate further comprises a second metallic layer formed on a second side of the electrically isolating substrate that is opposite the first side; and
the electrical power module further comprises at least one heat exchange feature extending from the second metallic layer.

3. The electrical power module according to claim 1, wherein the at least one encapsulant retention feature is co-formed with at least one electrical connection pillar of the electrical connection pillars.

4. The electrical power module according to claim 1, wherein the the encapsulant retention feature comprises an overhang.

5. The electrical power module according to claim 1, wherein the encapsulant retention feature comprises a lateral protrusion.

6. The electrical power module according to claim 1, wherein the encapsulant retention feature comprises a convex surface.

7. The electrical power module according to claim 1, wherein the encapsulant retention feature comprises a concave surface.

8. The electrical power module according to claim 1, wherein the encapsulant retention feature comprises a hole.

9. The electrical power module according to claim 1, wherein the encapsulant retention feature comprises a mesh.

10. An electronics package, for an electrical power module having an encapsulant encapsulating an electrical-component side of the electronics package, the electronics package comprising:
a base plate, comprising an electrically isolating substrate and a first metallic layer formed on a first side of the electrically isolating substrate and a second metallic layer formed on a second side of the electrically isolating substrate that is opposite the first side;
electrical connection pillars extending from the first metallic layer; and
at least one encapsulant retention feature extending from the first metallic layer and comprising at least one surface that is angled or parallel relative to the first side of the electrically isolating substrate and faces the first side of the electrically isolating substrate.

11. The electronics package according to claim 10, further comprising at least one heat exchange feature extending from the second metallic layer.

12. The electronics package according to claim 10, wherein the at least one encapsulant retention feature is co-formed with at least one electrical connection pillar of the electrical connection pillars.

13. The electronics package according to claim 10, wherein the encapsulant retention feature comprises an overhang.

14. The electronics package according to claim 10, wherein the encapsulant retention feature comprises a lateral protrusion.

15. The electronics package according to claim 10, wherein the encapsulant retention feature comprises a convex surface.

16. The electronics package according to claim 10, wherein the encapsulant retention feature comprises a concave surface.

17. The electronics package according to claim 10, wherein the encapsulant retention feature comprises a hole.

18. The electronics package according to claim 10, wherein the encapsulant retention feature comprises a mesh.
